(19) United States
(12) Patent Application Publication
(10) Pub. No.: US 2005/0067629 A1
(43) Pub. Date: Mar. 31, 2005

(54) Semimetal semiconductor

(76) Inventors: Jerry M. Woodall, New Haven, CT (US); Eric S. Harmon, Norfolk, MA (US); David B. Salzman, Chevy Chase, MD (US)

Correspondence Address: Attn: David Garrod, Ph.D., Esq.;Goodwin Procter LLP, 599 Lexington Avenue, New York, NY, 10022, US

(21) Appl. No.: 10/756,997

(22) Filed: Jan. 13, 2004

Related U.S. Application Data
(60) Provisional application No. 60/439,628, filed on Jan. 13, 2003.
(60) Provisional application No. 60/475,337, filed on Jun. 2, 2003.
(60) Provisional application No. 60/486,323, filed on Jul. 12, 2003.

(51) Int. Cl. H01L 33/00

(52) U.S. Cl. 257/101; 257/103

(57) ABSTRACT

Certain compound semiconductor materials can be formed with nearly metal-like conductivity, while retaining the crystalline structure, high mobilities, and high carrier velocities of conventional semiconductors. Such bulk and thin-film states of matter, method of creating them, devices formed therefrom, and applications benefiting from said devices and states of matter are disclosed herein.

### CROSS-REFERENCE TO RELATED APPLICATION

This application claims priority from U.S. Provisional Patent Applications “Semimetal Semiconductor,” filed Jan. 13, 2003; “III-V Devices on a Silicon Substrate,” filed Jul. 12, 2003 as docket L3176-016; and “Polycrystalline Microelectronic Devices,” filed Jun. 2, 2003 as docket L3176-014, all of which are incorporated by reference herein.

### FIELD OF THE INVENTION

This invention relates generally to the fields of solid-state physics and electronics, more particularly to the design and fabrication of semiconductor materials and devices, and still more particularly to the design and fabrication of semiconductor materials and devices for high-performance optoelectronic and microelectronic applications.

### BACKGROUND OF THE INVENTION

We term this new class of materials the semimetal semiconductors (“SMSC”). They have novel optical and electronic properties, notably characterized by their conductivity approaching that of metals.

The bulk, interface, and proximity properties of SMSC materials and their heterojunctions with conventional semiconductors have novel aspects, and offer a variety of materials science capabilities and new application opportunities, which are taught herein. Devices formed from SMSC materials can have or combine structures that are amorphous, polycrystalline, metamorphic, or single crystal. Benefits include some combination of: high electrical conductivity (exceeding 10⁴ mhos); high free carrier concentrations (greater than 1×10¹⁹ cm⁻³, greater than 2×10¹⁹ cm⁻³, greater than 4×10¹⁹ cm⁻³, greater than 8×10¹⁹ cm⁻³, or greater than 10²⁰ cm⁻³); said free carriers exhibiting high mobility (100-100,000 cm²/V-s); long mean-free scattering lengths (10-1000 nm) of carriers; high intrinsic fields across heterojunctions (exceeding 10⁷ V/cm); surface states (such as occur at grain boundaries, dislocations, heterojunctions, or free surfaces) that exhibit a donor (or acceptor) property with a low ionization energy (<10 kT, such that a significant fraction are ionized at the operating temperature); and/or a low density of surface states such that the average bulk Fermi level position is substantially flat (to within 3 kT).

In the preferred embodiment, SMSC materials can be formed by hyperdoping those III-V semiconductors that exhibit an intrinsic electron affinity (in the undoped material) of more than 4.1 eV. A high intrinsic electron affinity is necessary to prevent self compensation by native states, often called DX centers. It is not generally possible to achieve SMSC materials in semiconductors with electron affinities below 4.1 eV, because DX self compensation results in an upper doping limit of 1×10¹⁹ cm⁻³.

### OBJECTS OF THE INVENTION

Objects of the invention include, in contrast to the prior art: faster microelectronic devices at a given feature size, faster microelectronic devices achieved through the use of thinner epitaxial layers (e.g. base region of a HBT), faster microelectronic devices achieved through the use of higher conductivity layers, ballistic transport devices with cruder lithographic feature size, ballistic transport devices with longer mean free paths, unique quantum-confined devices, broad spectrum tunable lasers, extremely-low resistance interconnects and contacts; and SMSC materials enabling devices that are fault-tolerant and metamorphically integratable with legacy semiconductors including GaN, GaAs, InP and Si.

In brief, we argue the following:
A new growth technique enables a new materials system: the semimetal semiconductors (SMSC).
The growth technique follows from deep insights into the thermochemistry of materials.
It is proven and uses standard, unmodified commercial equipment.
The new materials system is fundamentally superior to existing semiconductor materials and their extrapolations into the future.
The materials promise a revolutionary jump in device performance for existing and novel semiconductor and quantum confined devices, through benefits like unprecedented conductivity for normal (i.e. non-superconducting) materials.
The new materials give devices using them such good tolerance of large feature size, defect-density, and compositional tolerance that they are producible in a markedly faster turnaround cycle. This cycle time is itself a benefit, and contrasts with the hugely expensive fabs and multi-month runs typically required to demonstrate comparable performance in GaAs, InP, or SiGe-for cases where those materials can compete at all.
Additionally, some of the SMSC materials are chemically inert and crystallographically compatible with Si and other standard compound semiconductors, so may be integrated metamorphically on them, enabling hybrid SMSC/semiconductor devices with unprecedented properties and performance.

SMSC materials combine some of the best of metal and semiconductor properties: high mobilities, high carrier concentrations, conductivity nearly as high as true metals, the same crystalline and band structure as conventional semiconductors, and excellent compatibility with Si, its oxides, and III-V compounds.

Semimetal semiconductor devices have been deemed interesting for forty years, but were deemed unbuildable for materials reasons (e.g. silicides trapping the electrons, dopants migrating from thin layers, unstable high doping levels, and compensation at high doping levels resulting in degraded electrical properties. Prior attempts to build semimetal semiconductors combined the worst of metal and semiconductor properties, including lower mobilities than semiconductors, lower carrier concentrations than metals, conductivity intermediate between semiconductors and metals; and in junctions with semiconductors, they suffered from unsuitable band structures and unstable metallurgy.

Results obtained using MBE-based hyperdoping techniques to deposit single crystal SMSC materials have proven that epitaxial InAs on GaP substrates¹ and n⁺⁺ InP can be formed as SMSC materials.
¹ J. C. P. Chang, T. P. Chin, and J. M. Woodall, “Incoherent interface of InAs grown directly on GaP(100),” Appl. Phys. Lett. 69 (1996) 981.

SMSC materials in heterojunctions exhibit excellent compatibility and stability with a broad range of III-V semiconductors, proving a general ability to create innovative heterojunction devices based on SMSC/semiconductor interfaces. The materials results are so dramatic and so generically applicable to applications requiring high performance semiconductors, and the processing technologies are so straightforward to apply and improve, that a measure of this invention's utility and novelty will be the this invention will be the extent and rate of its adoption.

Epitaxial growth techniques producing both bulk and extremely thin, defect-free SMSC materials include Liquid Phase Epitaxy (LPE), Chemical Vapor Deposition (CVD), and Molecular Beam Epitaxy (MBE). Other techniques may emerge in the future in the spirit of these, so are anticipated hereby by this disclosure.

Some SMSC materials exhibit a unique property whereby surface states act as shallow dopants (rather than as the deep levels typical of conventional semiconductor materials). Free surfaces, dislocations, and grain boundaries can therefore be employed to dope such materials. This is useful for enabling a polycrystalline devices containing SMSC material to exhibit useful semiconducting properties such as high free electron concentrations, reduced surface state scattering, and/or high mobilities.

It is well-known that certain defect states are associated with free surfaces, grain boundaries, and dislocations. In normal semiconductors, these defect states are usually deep levels that trap free carriers, depleting the surrounding material. A useful property of certain SMSC materials is that their surface states act as shallow donors (or shallow acceptors), with the benefits of the formation of a surface accumulation region, shielding these surfaces and lowering the potential barrier for transport across surfaces (such as across grain boundaries), that defects are shielded and less deleterious, and/or that bulk material is effectively doped n-type, or both. (This teaching generalizes to the complementary case of converting a defect's accumulation region into a depletion region, and doping the material p-type.)

For example, the deposition of SMSC InAs on a “bad” substrate such as polysilicon, SiO₂, or lattice-mismatched semiconductors still produces excellent semiconducting properties even though the InAs is highly defected or polycrystalline. A polycrystalline field-effect transistor (FET) produced using SMSC thin films consequently is capable of achieving comparable or better performance than many crystalline FETS, including silicon and compound semiconductor FETs! We have measured mobilities of 1500 cm²/V-s in polycrystalline InAs. Polycrystalline FETs using SMSC materials improve thin-film transistor technology by enabling high performance to be achieved on cheap, large area substrates, and by enabling the monolithic integration of high-frequency and power devices on wafers of silicon CMOS.

Unlike true metals, SMSC materials can be produced in conventional MBE chambers in unbroken, pinhole-free, highly conductive films as thin as 25 Å. Semiconductors this thin conduct poorly due to low conductivity and surface depletion effects.

Polycrystalline devices using SMSC materials can be deposited at substrate temperatures low enough for pre-existing silicon VLSI devices to survive, so SMSC devices can also be built on fully processed silicon wafers. This is valuable for single-chip solutions to many high-speed and wireless applications, as well as many other applications requiring a compound semiconductor device integrated monolithically with silicon devices.

The use or avoidance of handshake layers between the silicon and the SMSC material depends on the detailed requirements of the SMSC material's grain structure and standard metallurgical considerations. Some devices will rely on carriers transported across this heterointerface. For example, SMSC materials make metal-base transistors practical, and such devices may use silicon, non-SMSC compound semiconductors, or both. For example, a metal-base transistor could use conventional InP for the emitter and collector, and SMSC InGaAs as the base, relying on the electron affinity difference between InGaAs and InP to provide junction isolation. The high conductivity of the SMSC InGaAs metal base layer enables the base to be very thin, reducing scattering losses in the base (equivalent to minority carrier recombination in conventional bipolar junction transistors). A further advantage of the use of very thin SMSC InGaAs base regions is due to the fact that lattice matching constraints are relaxed, allowing pseudomorphic InₓGa₁₋₋ₓAs (for instance, where x>50%, x>60%, x>70%, or x>80%) to be used. SMSC materials with high InAs concentrations generally exhibit better conductivity properties than SMSC materials with high GaAs concentrations.

Other devices will rely on carriers transported within the SMSC material without them passing to or from the neighboring material at that place and time. For example, an InAs channel created as a SMSC material can be used as the n-type contact region for the preceding HBT, offering nearly metallic conductivity without the need for alloying (which normally requires a high temperature step). The surface accumulation property of many SMSC materials results in extremely low resistance ohmic contacts, because little or no depletion region will exist between some metals and some SMSC materials. Replacing polysilicon with a SMSC material can give CMOS-based electronics a performance boost commensurate with the use of so-called low-k dielectrics.

The properties of SMSC materials promise a wide range of useful, non-obvious transport phenomena. SMSC materials uniquely combine the very low sheet resistance of metals (allowing thinness), nearly perfect crystalline lattice, clean planar interfaces, an electronic band structure compatible with “normal” semiconductors, and long mean free electron paths (enabling fast equilibrium and non-equilibrium transport) even in the presence of a high defect density and small grain size.

### SUMMARY OF THE DRAWINGS

FIG. 1A illustrates the general area of application of the invention, comparing prior art with the invention.

FIG. 1B shows the preferred embodiment of the invention.

FIG. 2 illustrates a Schottky diode in accordance with the invention.

FIG. 3 illustrates a metal base transistor in accordance with the invention.

FIG. 4 depicts the band diagram for a metal-base transistor in accordance with the invention.

FIG. 5 illustrates the epitaxial layer structure of a heterojunction bipolar transistor (HBT) in accordance with the invention.

FIG. 6 illustrates an HBT in cross section, fabricated in accordance with the invention.

FIG. 7 illustrates an interconnect semimetalization in accordance with the invention.

FIG. 8 illustrates a MISFET in accordance with the invention.

### DETAILED DESCRIPTION OF THE INVENTION

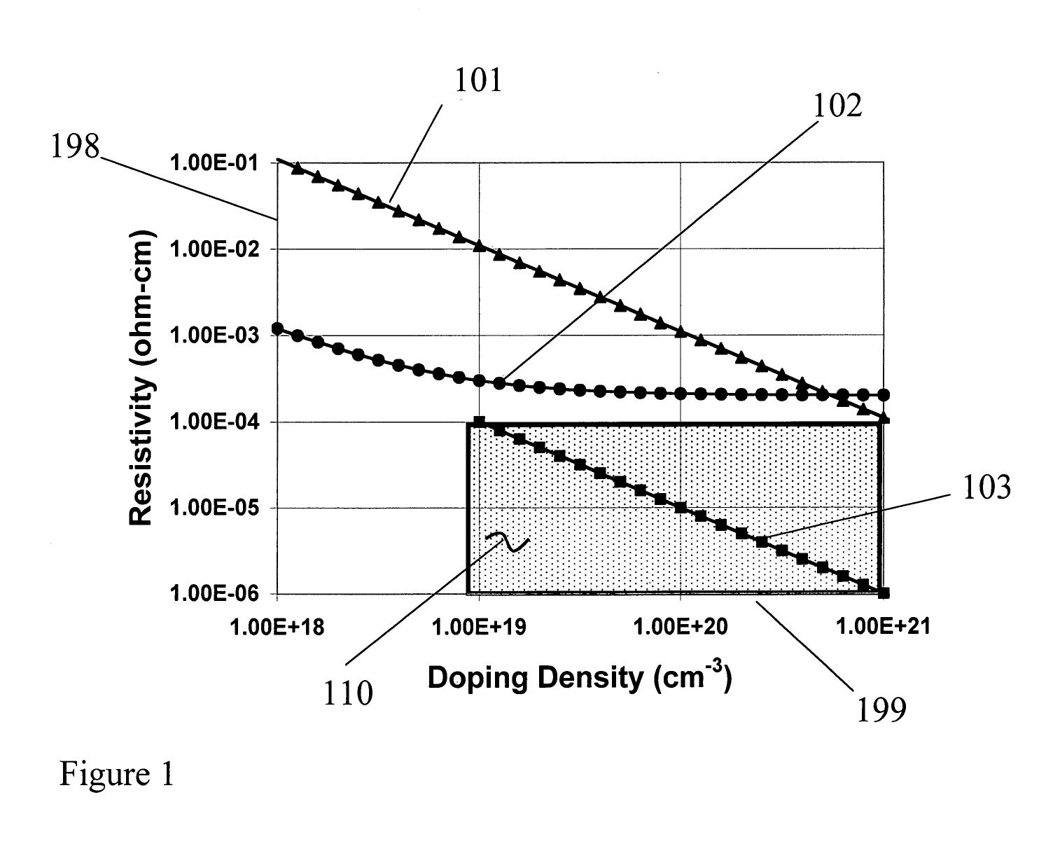

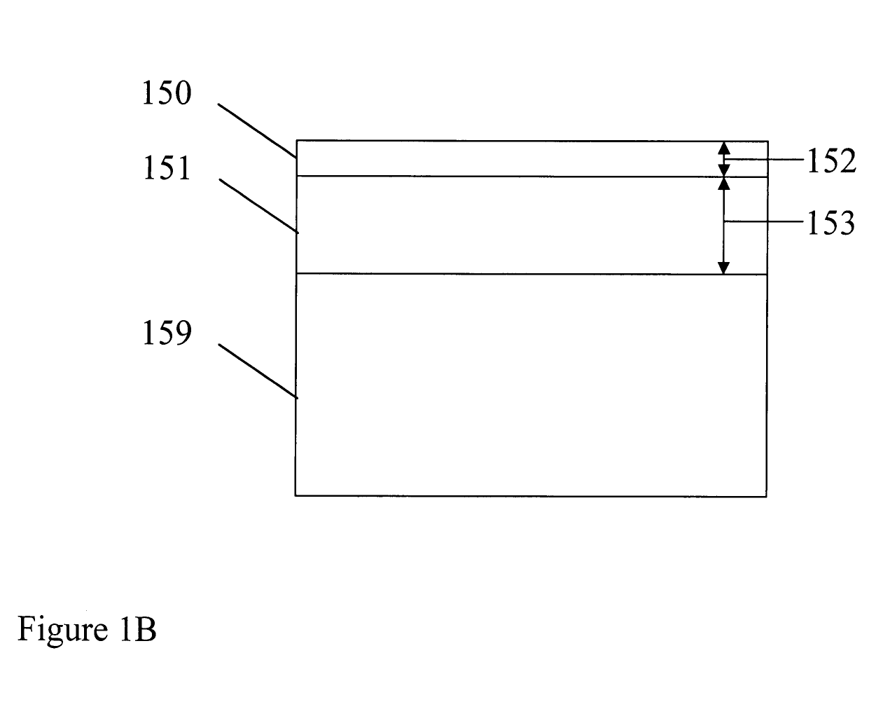

Reference is now made to FIG. 1, which depicts the region of application of the invention. Resistivity is plotted as a function of doping for materials created by prior art techniques and in accordance with the invention. In certain materials, a higher dopant concentration supports higher conductivity.

Reference is now made to FIG. 1A. FIG. 1A illustrates the region of applicability of the invention for n-type materials. The x-axis 199 is the doping concentration in cm⁻³. The y-axis 198 is the resistivity in Ohm-cm. Line 101 represents prior art materials such as silicon which exhibit a gradual decrease in resistivity as the doping 199 is increased. In the prior art, the resistivity remains above 10⁻⁴ ohm-cm even for doping levels as high as 1×10²⁰ cm⁻³. Line 102 represents prior art materials such as GaAs doped with silicon, which exhibit a saturation in resistivity as doping is increased beyond 1×10¹⁹ cm⁻³ due to self-compensation by DX centers. Line 103 shows the characteristics of a SMSC material, such as InAs doped beyond 1×10¹⁹ cm⁻³ using a technique such as hyperdoping to ensure high mobility even at such heavy doping. Note that some SMSC materials may exhibit a similar saturation effect as represented by line 102, yet they remain SMSC materials as long as the magnitude of the resistivity is less than 1×10⁻⁴ ohm-cm. Region 110 shows the area of applicability of SMSC materials, and is bounded by a doping density above 1×10¹⁹ cm⁻³ along with a resistivity below 1×10⁻⁴ ohm-cm.

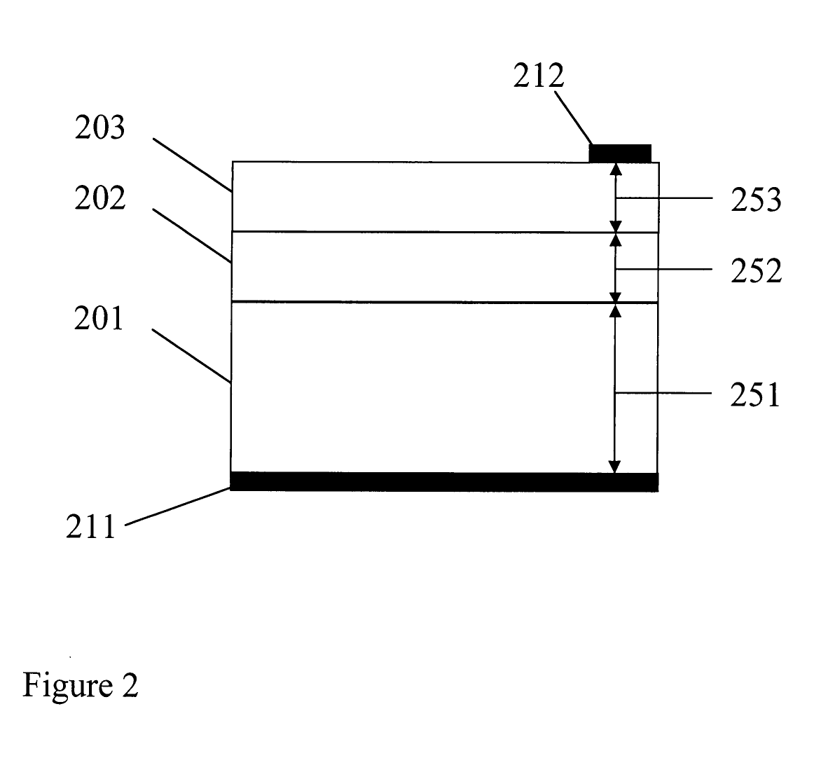

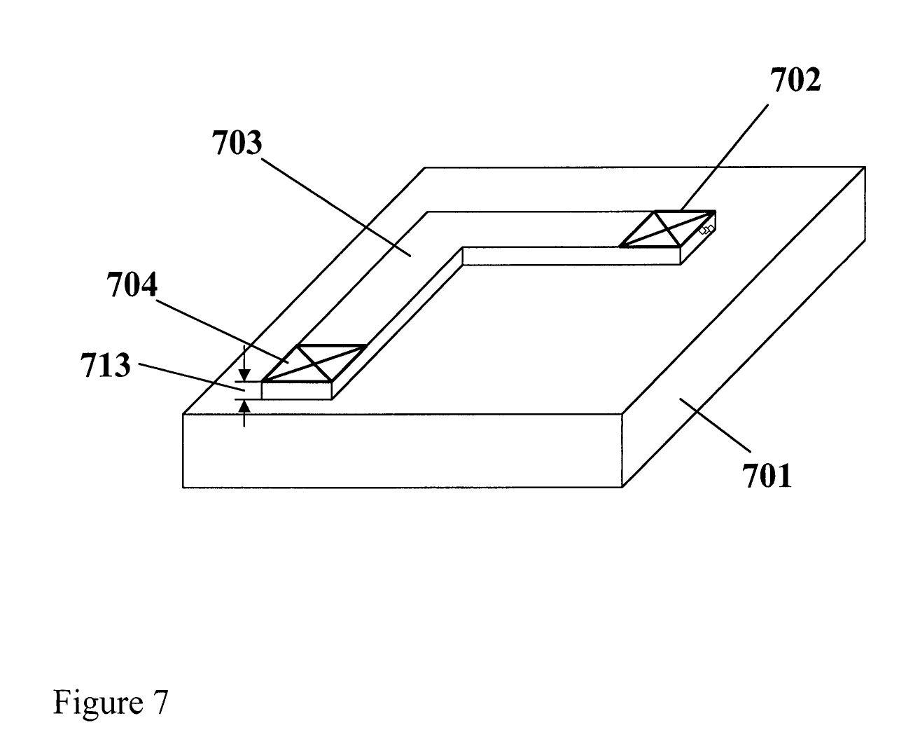

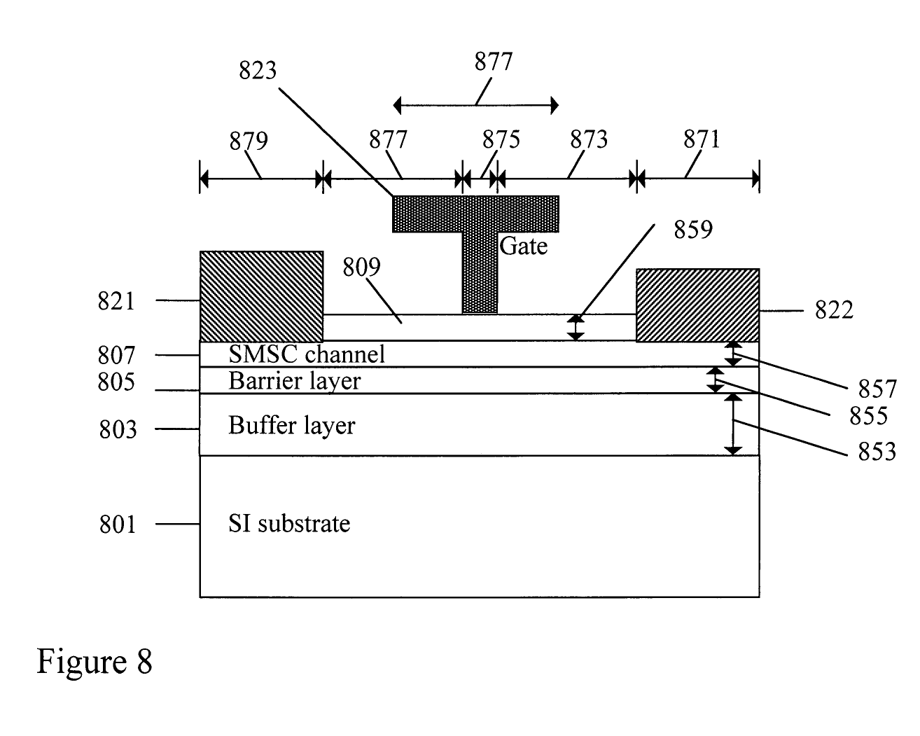

Reference is now made to FIG. 1B. FIG. 1B illustrates the preferred embodiment, which consists of a SMSC layer 150 deposited on a single crystal substrate 159. In the preferred embodiment, the single crystal substrate 159 is undoped GaP, the metamorphic buffer layer 151 is p-type InAs doped to 1×10¹⁷ cm⁻³ using Be, and the SMSC layer 150 is n-type InAs doped to 1×10²⁰ cm⁻³ using Si. The thickness 152 of the SMSC layer is 100 nm, and the thickness 153 of the buffer layer is 2.0 μm. Such a SMSC layer is useful for devices such as a Schottky diode (see FIG. 2), an interconnect layer (see FIG. 7), a metal-insulator-semiconductor field-effect transistor (MISFET—see FIG. 8), or a Hall effect sensor.

Reference is now made to FIG. 2. FIG. 2 shows a Schottky diode fabricated using a SMSC material in the place of the conventional metal-semiconductor contact. The device structure is grown on a substrate 201, such as a n-type GaP substrate with a thickness 251 of 500 μm. A buffer layer 202 is grown on top of the substrate 201 to a thickness 252. In this alternative embodiment, buffer layer 202 is epitaxial n-type GaP doped to 1×10¹⁷ cm⁻³, 5 μm thick. An n-type InAs SMSC layer 203 is metamorphically grown on top of the n-type GaP layer 202 to a thickness 253 of 100 nm. The GaP side contact 211 is made to the back side of the n-type GaP substrate 201, while contact to the SMSC layer 203 is made through contact 212. This device exhibits the rectifying characteristics of a Schottky diode, due to the fact that the SMSC layer 203 exhibits metal-like characteristics, and the conduction band discontinuity between the SMSC layer 203 and the GaP layer 202 is sufficiently large to prevent ohmic current flow. This Schottky diode device would be useful as a high power rectifier with a large voltage blocking capacity.

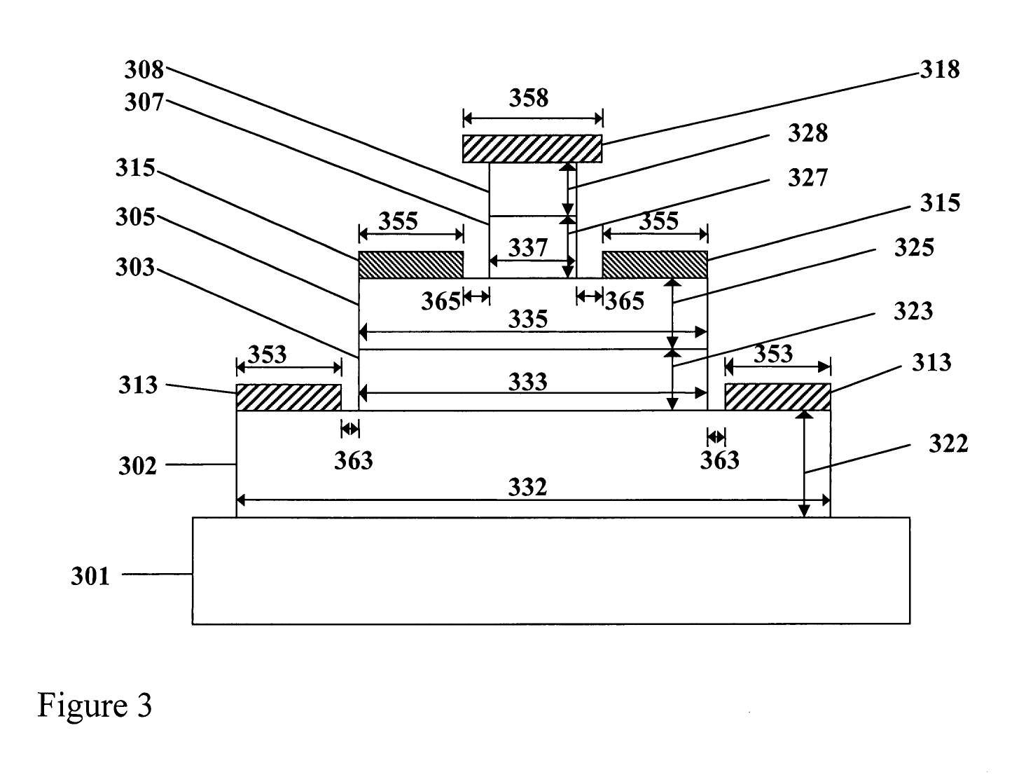

Reference is now made to FIG. 3. FIG. 3 shows an alternative embodiment where the SMSC material is used to enable a metal base transistor. FIG. 3 shows the layer stack that is grown by MBE, MOCVD, or any other growth technique with properties adequate to produce the required semiconductor and SMSC layers. The layer stack consists of high quality semiconductor layers grown on a substrate 300, which in this alternative embodiment is InP. A buffer 301 is grown to provide a high quality superstrate for the subsequent growth of the active layers of the device. The composition of the buffer layer and the thickness 381 are chosen to optimize the quality of the layers grown on top. A subcollector 302 is grown with a thickness 382 to provide a low resistance contact to the collector region of the HBT. In the preferred embodiment, this region consists of 1000 nm of n-InP doped to 5×10¹⁸ cm⁻³. The first part of the collector region 303B consists of n-InP doped to 1×10¹⁸ cm⁻³ with a thickness 383B of 100 nm. The second part of the collector region 303A consists of undoped InP with a thickness 383A of 200 nm. The FIG. 3 shows the cross-sectional geometry of the device fabricated using prior art mesa isolation techniques. This is a mesa-isolated structure where layer 308 is the emitter contacting layer, consisting InGaAs lattice matched to InP, with a n-type doping density of 1×10¹⁸ cm⁻³, layer 307 is the emitter, consisting of InAlAs lattice matched to InP with a n-type doping density of 1×10¹⁷ cm⁻³, layer 305 is the SMSC metal base layer consisting of SMSC n-type In_{0.75}Ga_{0.25}As doped to 1×10²⁰ cm⁻³ with silicon, with a thickness 325 of 10 nm, layer 303 is the collector, layer 302 is the sub-collector, and 301 is the substrate. The emitter contacting layer has a width 337 and a thickness 328. The emitter has a width 337 and a thickness 327. The base has a width 335 and a thickness 327. The collector has a width 333 and a thickness 323. The subcollector has a width 332 and a thickness 322. The emitter contact 318 has a width 358. The base contacts 315 have a width 355 and a spacing 365 from the edge of the emitter 307. The collector contact 313 has a width 353 and a spacing 363 from the edge of the collector 303. The invention is applicable to many other well-known configurations, but this one is chosen to illustrate the concepts and should not be construed as limiting or exhaustive. The preferred embodiment of the invention achieves metal base transistor performance by enabling ballistic transport of electrons injected from emitter 307 into base 305. Due to the conduction band offset between InAlAs and In_{0.75}Ga_{0.25}As, electrons are injected with over 0.5 eV of excess energy. As long as the scattering length in the base is long enough, and given that the quantum mechanical reflection coefficients at the base-collector junction are small enough, efficiency hot electron transport may be achieved, and therefore a high performance metal base transistor can be achieved.

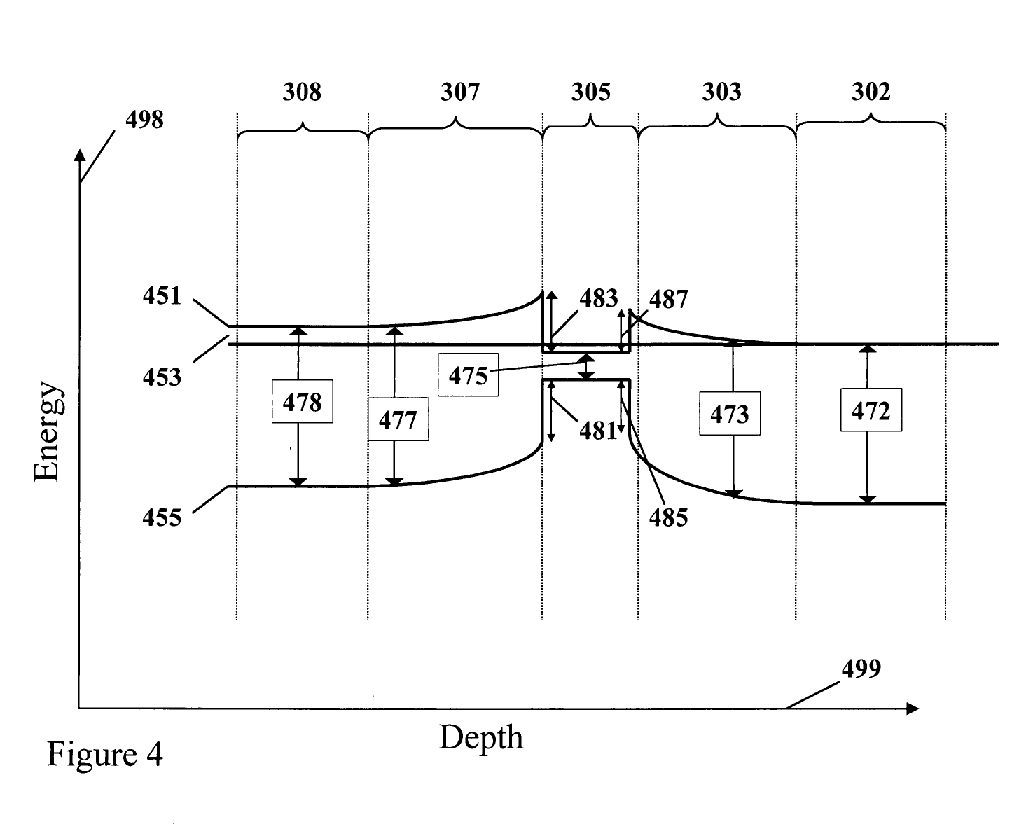

Reference is now made to FIG. 4, which shows the band diagram of the metal base transistor. The potential energy 498 of the conduction band 451 and valence band 455 are plotted as a function of vertical position (depth) 499 through the device. Layer 308 has a band gap 478, and layer 307 has a band gap 477, layer 305 has a band gap 475, layer 303 has a band gap 473, layer 402 has a band gap 472. The conduction band offset at the base emitter junction is 483 while the valence band offset is 481. The conduction band offset at the base collector junction is 487 while the valence band offset is 485.

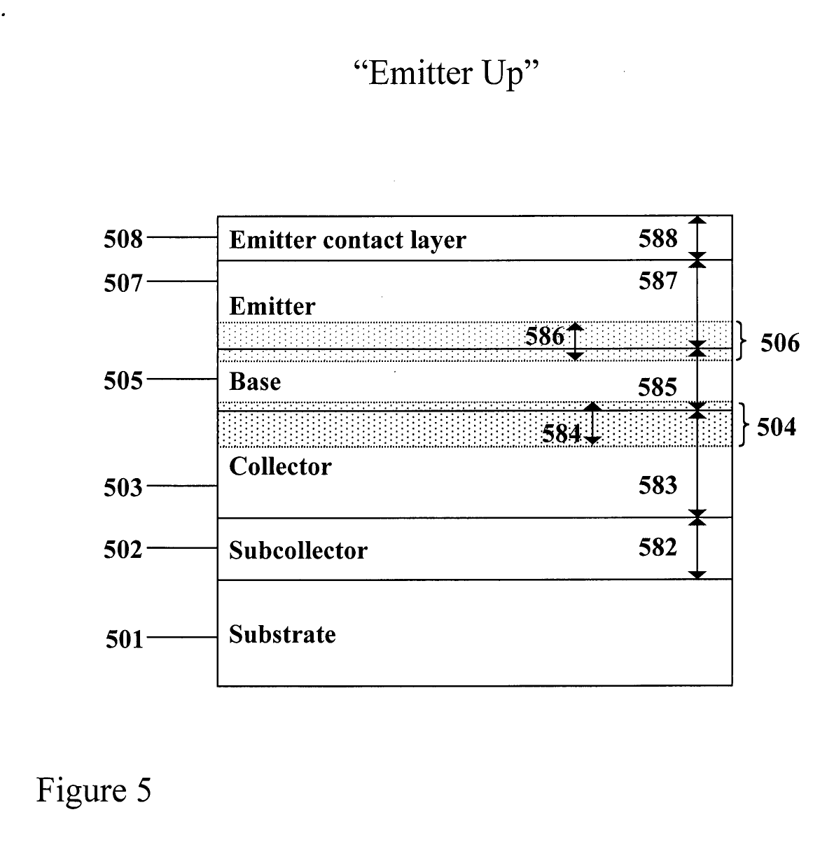

FIG. 5 show the layer structure of a pnp HBT structures incorporating SMSC materials. The figure is enlarged in cross-section, rather than to scale, so the epitaxial layer structure of a conventional prior art HBT may be seen. Epitaxial techniques such as MBE, MOCVD or LPE are typically used to grow high quality crystalline layers on a substrate 501. The layer stack includes a sub-collector 502 of thickness 582 designed to provide a low resistance path between the collector 503 and the collector contact 513. The collector 503 thickness is 583. In high-performance pnp HBT designs, the sub-collector is usually a heavily doped p-type semiconductor and the collector is a lighter doped p-type region. The junction between the collector 503 and the n-type SMSC base layer 505 results in a depletion region 504 with a width 584. Likewise, the junction between the n-type SMSC base layer 505 and the p-type emitter 507 is the emitter-base depletion region 506 with a width 586. The base 505 has a thickness 585, and the emitter 507 has a thickness 587. A heavily doped p-type emitter contacting layer 508 of thickness 588 is ordinarily deposited on top of the emitter 507 to facilitate ohmic contacts to the emitter. Not all HBT designs will use all the layers described, but every HBT incorporates at least one collector region 503, one base region 505, and one emitter region 507.

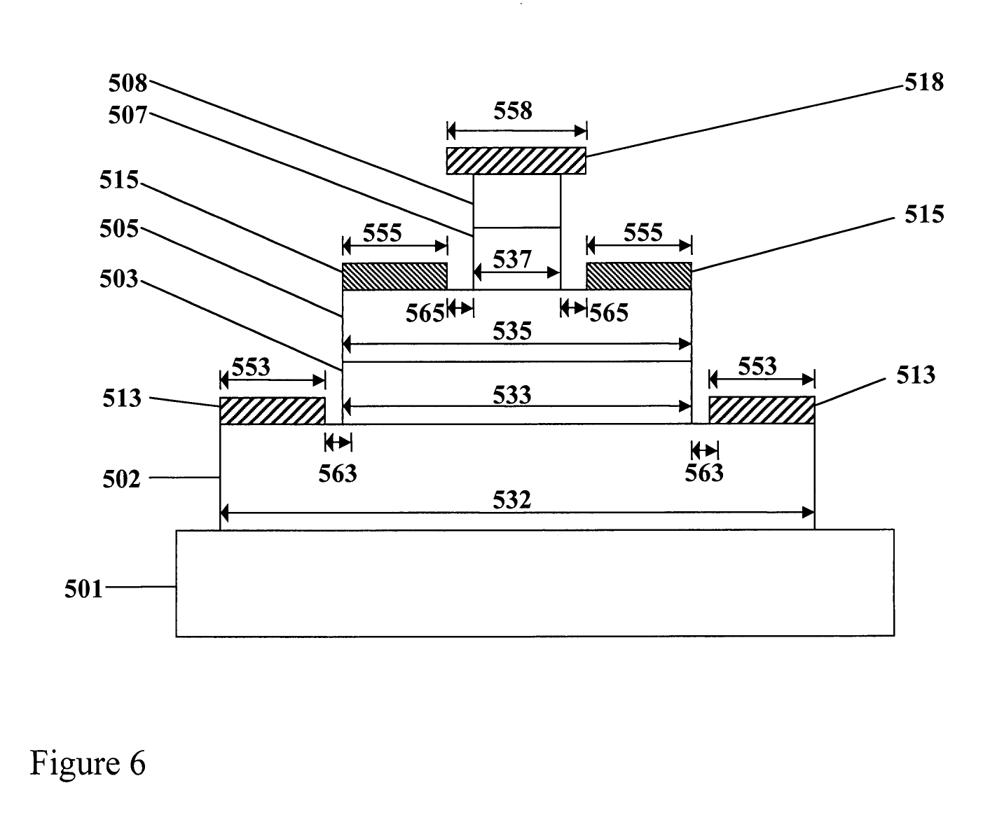

After growth of the layer structures represented in FIG. 5, HBT devices are ordinarily fabricated subtractively using a mesa isolation geometry as shown in FIG. 6. In FIG. 6 the layers 501, 503, 505, and 507 are defined as the substrate, collector, base, and emitter, respectively, and correspond to the same layers as in FIGS. 5. In FIG. 6, an emitter mesa contact 518 with a width 558 makes a low resistance ohmic contact to the emitter mesa through the emitter contacting layer 508. The lateral extent of the emitter mesa is 537, which defines one dimension of the emitter area. The base contacts 515 with a width 555 make a low resistance ohmic contact to the base region 505 of the HBT. Note that this cross section assumes that 515 and 513 are ring contacts. The base contacts 515 are spaced a distance 565 from the emitter mesa, which may be advantageously designed to reduce the base current due to minority carrier recombination at the base contacts 515. The base mesa lateral extent is 535. Collector contacts 513 with a width 553 make ohmic contact to the subcollector region 502. The collector contacts 513 are spaced a distance 563 from the base mesa to facilitate fabrication. The collector lateral extent is 533. The area of the emitter is defined by the area of the emitter mesa 507 that is in contact with the base 505, and is defined by a lateral extent 537 and a transverse extent 577 shown in the overhead view of FIG. 2B. The width of the emitter contact 558 is usually different than the width of the emitter 537 due to the undercutting of the emitter mesa etch. Likewise the transverse extent of the emitter contact 578 is usually different from the width of the emitter 577. The area of the base-collector junction is defined by the area of the base mesa 505 that is in contact with the collector 503, and is defined by a lateral extent 535 and a transverse extent 575. The area of the sub-collector mesa 502 has a lateral extent 532 and a transverse extent 573. The area of the base 505 that is outside the emitter-base junction is referred to as the extrinsic base, which generally contributes parasitic capacitance to the transistor, but is necessary to achieve low resistance ohmic contacts to the base. Likewise, a significant fraction of the base-collector junction under the extrinsic base is also called the extrinsic collector, and likewise contributes parasitic elements to the transistor, resulting in degraded transistor performance.

The HBT device shown in Figures and 6 may be operated by applying a voltage between the base contact 515 and the emitter contact 518 to modulate the current through the collector contact 513. The carriers of the current are holes because the n-type SMSC base region 105 is n-type.

Reference is now made to FIG. 7, which shows how a SMSC layer 703 of thickness 713 may be used to make low resistance contacts to points 702 and 704. Layer 703 is deposited on top of layer 701, and can be used to make low resistance contact between two circuit elements.

Reference is now made to FIG. 8. SMSC materials allow significant performance enhancements to be achieved for field effect transistors, such as the metal oxide semiconductor heterostructure FET (MOSHFET). The general MOSHFET structure consists of a sequence of semiconductor layers on a substrate 801. Common substrate materials include wafers of Si, GaAs, InP, and other materials available from semiconductor supply houses, notably semi-insulating GaAs. An optional buffer layer 803 with thickness 853, such as crystalline GaAs, is advantageously located on top of the substrate 801, if needed to ensure a clean, nearly monocrystalline template for further growth. A optional barrier layer 805 of thickness 855 is located above 803, if present. A SMSC channel region 807 of thickness 857 is located above 805. In order to optimize MOSHFET performance, a high sheet carrier density is desirable. For example layer 807 may consist of In_{0.50}Ga_{0.50}As doped to 1×10²⁰ cm⁻³, 10 nm thick, in order to obtain a sheet carrier density of 1×10¹⁴ cm⁻³. After the growth of SMSC layer 807, growth is terminated and the substrate removed from the epitaxial system. A gate insulator layer 809 of thickness 859 is deposited to form the gate region. Wet chemical etching is used to remove the gate insulator layer from the regions where source contact 821 and drain contact 822 make contact to the SMSC channel 807. The MOSHFET may have other layers, but the common features are ordinarily as described herein. The inventors anticipate the addition or deletion of other layers, or reordering or renaming of the canonical layers enumerated herein, still produces a FET in accordance with the invention. Not all layers are used in all designs, but all MODFET designs require a channel 807 and a gate layer 809. Each layer usually differs from other layers in some semiconductor material property, such as band gap, doping, electron affinity, lattice constant, or some combination of these parameters. Within each layer, these parameters may be varied as a function of vertical position in the device (where vertical orientation accords with FIG. 8) if warranted by the MOSHFET design.

Transistors are fabricated by depositing gate 823 on top of the gate insulator 809. Contacts 821 and 822 are deposited directly onto the SMSC channel layer 807 and do not need to be alloyed because low resistance ohmic contacts to the SMSC channel layer 807 is readily achieved with almost any metal/semiconductor contact.

A voltage applied to the gate is used to modulate the conductivity of the channel and hence the output characteristics of the MODFET. Current in the channel is proportional to the product of electron mobility, carrier density, and the applied electric field across the source 821 and drain 822 contacts.

### DISCUSSION OF THE INVENTION

The simplest definition of a SMSC material is functional: any semiconductor combining high mobilities and high carrier concentrations to achieve resistivities smaller than 100 μΩ-cm. Tighter definitions constrain resistivities to below 50, 40, 30, 20, or 10 μΩ-cm. True metals such as Cu and Al achieve resistivities in the range of 1 to 10 μΩ-cm, but the semiconductor Si is not a SMSC material even at doping densities as high as 1×10²¹ cm⁻³ since its mobilities are too low and its minimum resistivity is about 150 μΩ-cm.

The surface states of some SMSC materials are located within a few kT of the conduction band edge, rather than deep inside forbidden band gaps. (Or, equivalently, in the valence band.) Therefore, these surface states act as shallow donor sites (or, equivalently, shallow acceptor sites) rather than mid gap traps, and surfaces of these SMSC materials normally exhibit free carrier accumulation rather than depletion. These unique surface properties enable a new class of highly defected materials such as metamorphic or polycrystalline devices that do not exhibit the severe mobility degradation normally associated with grain boundaries and dislocations.

Producing SMSC materials requires a means for producing heavy doping while maintaining high mobilities. We have developed a “hyperdoping” technique that does this, giving doping levels above 1×10¹⁹ cm³ and achieving conductivities higher than 100 mhos. In an alternative embodiment, a SMSC material could be produced by a method for increasing the conductivity in a material with high enough carrier density, for example by using quantum confinement to reduce scattering.

SMSC devices can be divided into two general classifications: crystalline and polycrystalline. Crystalline devices incorporate SMSC materials grown on lattice-matched substrates, strained pseudomorphic SMSC layers, and strain-relaxed (metamorphic) SMSC layers grown on lattice-mismatched substrates. Crystalline devices will often incorporate heterojunctions to conventional semiconductors. Polycrystalline devices may be produced by depositing SMSC materials on nearly any substrate, including glass, quartz, sapphire, and polymers, opening up an entirely new class of applications for SMSC materials; they may include microcrystalline and amorphous materials too. We disclose below the remarkable fact that polycrystalline devices using SMSC materials achieve very high conductivities, even in the presence of a high density of grain boundaries.

TABLE I
Examples of SMSC materials. Additional SMSC materials
can be created by use of the principles enumerated herein, and
quaternary combinations of the materials in this table (i.e.
InGaAsP) may also be useful SMSC materials. Conversion of
conventional semiconductors can be achieved if the electron
affinity is larger than 4.1 eV. For semiconductors with an
electron affinity less than 4.1 eV, conversion to a SMSC
material is not generally possible due to self compensation by
DX centers.

| SMSC | Electron | | |
|---|---|---|---|
| material | affinity | | Comments |
| InAs | 4.9 | eV | Good SMSC properties have been proven |
| | | | experiment for this material. |
| InP | 4.38 | eV | We Good SMSC material is produced by |
| | | | hyperdoping this material n-type to |
| | | | 1 × 10²⁰ cm⁻³ |
| InAsP | 4.38-4.9 | eV | This ternary material system should enable |
| | | | SMSC materials with a band gap tunable |
| | | | from 0.35 eV (InAs₁P₀ = InAs) to 1.35 eV |
| | | | (InAs₀P₁ = InP). |
| InGaAs | 4.1-4.9 | eV | SMSC properties can be achieved even for |
| | | | high Ga mole fractions up to In_{0.05}Ga_{0.95}As |
| InAlAs | 4.1-4.9 | eV | SMSC properties should be feasible for Al |
| | | | concentrations as high as 40% |
| InSb | 4.59 | eV | The high electron affinity of InSb makes it |
| | | | an i [symbol] candidate for conversion into a SMSC |
| | | | material |
| InN | ? | | The electron affinity of InN is not precisely |
| | | | kn [symbol] but is expected to be larger than 4.1 eV |
| InAsN | InAsN | | Since both InAs and InN have an electron |
| | | | affinit [symbol] larger than 4.1 eV, InAsN should |
| | | | be a SMSC mater for all compositions |
| InGaSb | 4.1-4.59 | eV | SMSC properties can be achieved for |
| | | | Gallium concentrations as high as 90% |

Many of the advantages of a SMSC materials can be achieved in substantially 2D configurations using conventional semiconductors with modulation doping techniques, such as often used in HEMT and pHEMT structures. Typically, such modulation doping results in confinement of the free carriers in one or more dimensions, and therefore results in a degradation of the electron transport properties along that dimension. Therefore, modulation doping does not provide the general solution that SMSC materials may provide. For example, vertical transport through a modulation doped structure is affected by the potential barriers caused by the heterojunction and doping modulation, generally resulting in very low vertical mobilities. SMSC materials do not need to use the same heterojunction and doping modulation, and therefore exhibit significantly different vertical transport properties. The SMSC material may also produce a high conductivity two-dimensional electron gas (2DEG) like a PHEMT or HEMT structure, but be deposited conformally (such as through epitaxial regrowth) where the HEMT and PHEMT cannot. In some embodiments, devices may incorporate both SMSC materials and modulation doping techniques to further increase conductivity, provide confinement, or produce some other desirable property, such as making a high charge carrier density available at, near or into an otherwise charge-poor material.

Lattice mismatching: SMSC materials have unique and interesting features. Because SMSC materials are relatively tolerant of crystalline defects such as dislocations and grain boundaries, one can tune the SMSC band gap over a large range without requiring a closely lattice-matched substrate, which is useful. Also, our MBE hyperdoping growth technique assures a high activation of dopant during growth, even when conventional techniques would result in dopant diffusion, precipitation or compensation. Table I lists some of the semiconductors whose SMSC embodiments we anticipate and teach in this disclosure.

Surface states: Some SMSC materials have surface states (e.g. at grain boundaries and dislocations) which do not introduce deep levels in the semiconductor band gap, where traps would degrade the performance of conventional semiconductors. Rather, surface states in these SMSC materials act a shallow donors or shallow acceptors, resulting in a very unusual property whereby the surface states act to provide rather than capture free carriers, and the density of free carriers so produced is determined by the surface area or dislocations density^{2,3}.
²H. Tsukamoto, E.-H. Chen, J. M. Woodall, and V. Gopal, “Correlation of defect profiles with carrier profiles of InAs epilayers on GaP,” Appl. Phys. Lett. v. 78, p. 952 (2001)

³V. Gopal, E. P. Kvam, T. P. Chin, and J. M. Woodal, “Evidence for misfit dislocation-related carrier accumulation at the InAs/GaP heterointerface,” Appl. Phys. Lett., v. 72, p. 2319 (1998)

Surfaces free of deep levels are also expected to enable unique metal-insulator-semiconductor (MIS) devices, where it becomes unnecessary to achieve a high quality interface between the insulator and the semiconductor, since the density of deep levels at the SMSC surface would be expected to remain low. Furthermore, the high density of free carriers in SMSC surface channel devices reduces the sensitivity of the channel modulation characteristics, thereby enabling higher performance even in the presence of a large density of surface states (see Khan, Muhammad Asif; et al., patent application 20020052076, May 2, 2002).

Another valuable feature follows from the surface and interface Fermi level being pinned above the conduction band minimum (by about 0.2 eV in InAs), which gives rise to a measured sheet concentration of 10¹⁴ electrons/cm² at any surface that is not passivated. Therefore, If we construct a composite film with interfaces with an average separation of 10 nm, this would produce a “bulk” electron concentration of 2×10²⁰ cm⁻³. Assuming just the measured mobility of 500 cm²V⁻¹s⁻¹ (see Table II), this “bulk” material would have a room temperature resistivity of 1/nμe=1/(2×10²⁰/cm³×1.6×10^{-19×500})=62 μΩ-cm, which only 30 times higher than the room temperature value of single crystal Cu, 2.1 μΩ-cm. Note that improved growth techniques may enable even higher mobilities to be achieved, hence lower resistivity.

Self doping by surface states is an attractive feature of InAs that may be exploited to provide high carrier concentrations in a thin InAs surface channel, such as might be present in a MISFET structure.

Polysilicon competitor: SMSC InP and InAs have a high electron concentrations and do not oxidize readily in air, so may be good microelectronic device interconnect materials. Polysilicon is commonly used today for chemical reasons, though its resistance is closer to 400 μΩ-cm, since it is compatible with semiconductors and oxides whereas Cu is highly reactive. We anticipate the use of SMSC materials for interconnects in microelectronic devices in the manner of polysilicon, notably silicon CMOS devices. This can bring benefits of alloy-quality contacts without the thermal budget required for alloying, improved inter-materials compatibility, use of a semiconductor instead of a metal like aluminum or copper, avoidance of polysilicon with its low conductivity, a reduced RC time constant, or some combination of these.

Polycrystalline interconnects formed from SMSC materials may be useful for FETs where simply depositing any suitable insulator enables field effect control of the channel conductivity, for HBTS, where the degradation in minority carrier lifetime at grain boundaries is suppressed due to the accumulation region surrounding the boundaries, and other microelectronic devices such as metal base transistors, diodes, and thyristors.

The room temperature conductivity of a quantum confined 2DEG is limited to about 1 kΩ/square. By using SMSC materials in a quantum well, it is possible to achieve a factor of 10-100 fold improvement in the room temperature conductivity of a channel, which enables a new tradeoff regime for SMSC field effect devices, SMSC quantum wires, and SMSC quantum dots.

Consider CMOS based VLSI and RFIC development. SMSC will enable ultra-high conductivity polycrystalline chip interconnects and semimetal gates, which will change how nanoscale CMOS VLSI systems will be realized. Local connections will be less limited by RC and will clock at closer to the device fT. SMSC materials are far more conductive than polysilicon, so interconnect dimensions can be scaled down considerably. This could enable much greater functionality to be achieved with the same number of conductor metalization layers.⁴ Many assumptions about interconnects in integrated circuits⁵ will need to be revisited, in light of the teachings of this invention. We anticipate those optimizations to the extent that they depend on the use of SMSC materials and are well-known in the fields of device physics, solid state physics, or electrical engineering. In CMOS RFICs today, resistive losses in the gate seriously degrade performance, resulting in lower efficiencies, lower operating frequency due to voltage droop along the gate (fₘₐₓ limitations), ⁴ W. Fang, A. Brunnschweiler, and P. Ashburn, “An Analytical Maximum Toggle Frequency Expression and Its Application to Maximizing High-Speed ECL Frequency Dividers.” IEEE J. of Solid State Circuits, 25(4), 8/1990. ⁵ T. C. Edwards and M. B. Steer, Foundations of Interconnect and Microstrip Design, Third Edition, John Wiley & Sons, 2000.

avoidable transmission line delay, and high parasitic losses. Each of these could be improved with trade-offs that are well-known to practitioners of circuit design by using poly SMSC in preference to polysilicon.

Ultra-thin Depletion Layers: In light of the high density of donor ions in SMSC materials, depletion layer widths can be made extremely narrow in accordance with the invention: well below 10 nm and possibly below 1 nm. We have already confirmed the high thermodynamic stability of the material and its dopants, due to deep local energy minima, so it is meaningful to contemplate stable 1 nm junctions! If charge carriers lie at a heterojunction interface, then the depleted, ionized donors form a counter-charge layer only 1 nm or so away, resulting in huge internal built-in electric fields, naively calculated to exceed 10⁷ V/cm. Unlike their behavior in more intuitive “3D” materials, these built-in electric fields need not result in dielectric breakdown or leakage, since the Fermi level can be flat even while the electric field is huge. We anticipate and teach using ultra-thin depletion layers in microelectronic devices. In prior art materials, such layers are unavailable even though valuable, but this invention enables them.

Intrinsic fields: An internal field in excess of 1×10⁷ V/cm across the heterojunction would be impossible in a classical material since it would exceed the Muller threshold for field emission! Such an electric field cannot however be precluded out-of-hand since other experimentalists have observed electric fields sustained in ultra-thin layers of wide band gap insulator far beyond what the bulk materials could “normally” tolerate. We recognize that this new SMSC materials class at the doping levels available here makes fascinating new phenomena available for study and engineering, including higher internal electric field limits.

Within these giant but extremely local built-in electric fields, devices can be designed to make all carrier motion ballistic, with the attendant opportunities for improvements in switching and modulation speed. For instance, the high electric field generated across a SMSC junction, together with ballistic carrier motion may make it possible for specially designed structures to become a negative electron affinity surface. realizing such structures allows injection of photo-generated free electrons (into space or into the material) with high efficiency, while preserving, for example, the circular polarization of a photon as the intrinsic spin of a photogenerated carrier.

This effect also works for internal photoemission from a SMSC material into a wide bandgap semiconductor or insulator. It provides opportunities in creating efficient spin-polarized currents in such wide bandgap materials so long as the field suffices to surmount typical heterojunction offsets.

These built-in electric fields are so large that they are unlikely to be screened out by surface states or surface ions, except for the worst surface state density on a SMSC-based device. If the band offset between a SMSC and an adjacent material is favorable, and if a large enough bandgap SMSC is used, then the adjacent material would develop highly charged accumulation or depletion layers, which would support novel physical properties. For instance, this makes it possible to provide “surface doping” to effectively dope the “invert” or “accumulate” materials that have never been considered usable as semiconductors. We anticipate such states, semiconductor devices using them, and methods for making them, to the extent they rely upon SMSC materials, devices, or methods for forming them.

Fundamental Optical Properties: Direct gap SMSC materials promise a new materials system for optoelectronic light generation. Among optoelectronic devices today, there is little or no doping in the active region of semiconductor lasers, and only modest doping in spontaneous emission devices like light-emitting diodes.

Nevertheless, there are real advantages for radiative electron-hole recombination to occur in a SMSC, rather than in a traditional semiconductor. Since both electrons and holes must present, radiative electron-hole recombination occurs at a rate proportional to the product of the two concentrations, Bnp, where B is the radiative recombination coefficient (=1.1×10⁻¹⁰ cm³s⁻¹ for traditional InAs), n is the electron density and p is the hole density. The actual recombination lifetime is 1/BP, if there is a large hole concentration P, or 1/BN is there is a large electron concentration N. Since SMSC materials have huge majority concentrations of electrons or holes, they can be made to exhibit shorter minority carrier lifetimes, hence faster modulation speed, more efficient lasing, and better efficiency of radiative versus defect-induced non-radiative recombination.

Where SMSC materials support avalanching, avalanche photodiodes with unprecedented properties enabled. Avalanche devices can also produce discrete, controlled, steep potential steps that generate a well-controlled step-wise electron avalanche, while preventing the holes from becoming ballistic due to shorter mean free paths. This can be used to solve the long-standing problem of reducing the avalanche noise in conventional III-V electron multiplier devices. The low ratio of saturated drift velocities for holes versus electrons provides a very low k-factor.

Quantum computing: SMSC materials may be useful for quantum computing applications such as inherently secure quantum telecommunications. There, a so-called “single photon gun” or fermionic “photon anti-bunching” is ordinarily used to emit a single photon, but only one photon, immediately after a triggering event. The fermion statistics of the carriers can be used to pack but separate the radiative events, but only if the minority carrier radiative recombination rate is considerably faster than has heretofore been available. The full benefits depend on there being a substantial dead-time between successive photons to ensure that the intended photon state is the one being measured, so a radiative recombination rate well above 10 GHz, perhaps above 100 GHz, may turn out to be required for a data rate in the 100 MHz range.

Radiative versus non-radiative recombination: In the past, heavily doped semiconductors have always been disadvantaged for light emission, since Shockley-Read-Hall and Auger recombination typically dominate at high carrier densities, offsetting the advantage of an increased radiative recombination rate at high carrier densities. The reason may be understood from the following formula for the overall recombination rate R of minority holes p in a large background density of majority electrons N, that includes Shockley-Read-Hall recombination A, as well as the Auger recombination coefficient C (=2.2×10⁻²⁷ cm⁻⁶ s⁻¹ for conventional InAs):
R=Ap+BNp+CN²p.

Optoelectronic design has consequently retreated to the safe territory of only modest doping, or no intentional doping.

But the Auger coefficient assumes bulk, unconfined structures, requiring that energy and momentum be conserved. With the advent of band structure engineering and quantum confinement, there is now appreciable control⁶ over Auger recombination channels. Auger is a non-radiative recombination mechanism, entailing the annihilation⁷ of an electron and a hole with the release of the bandgap energy E_{g} to a third carrier, with energy and momentum of course conserved. Low dimensional structures-such as strained quantum wells (2D), quantum wires (1D), and quantum dots (0D)—limit the available momentum and energy states for the carriers and so effectively diminish⁸ the Auger recombination probability (i.e. increase the time constant of its channel). In particular, if the potential well depth seen by a heavily doped carrier is higher than the bandgap energy E_{g}, there can be fewer states available to accept an Auger-excited carrier, so Auger recombination is substantially suppressed.
⁶ Yablonovitch, E.; Kane, E. O. “Reduction of lasing threshold current density by the lowering of valence band effective mass.” Journal of Lightwave Technology, vol. LT-4(5), May 1986. p. 504-6.

⁷ Herz, L. M.; Phillips, R. T.; Le Ru, E. C.; Murray, R. “Time-resolved photoluminescence cross-correlation measurements on InAs quantum dots.” Physica Status Solidi A, vol. 190, April 2002. p. 565-9.

⁸ Adams, A. R. “Band-structure engineering for low-threshold high-efficiency semiconductor lasers.” Electronics Letters, vol. 22(5), 27 Feb. 1986. p. 249-50.

Heavy doping: Under heavy doping conditions, the carriers would be easily degenerate, but the Fermi energy might fall in between the first and second states of a quantum dot: E₁<E_{F}<E₂. In such a quantum dot case, the heavy doping would have the effect of providing a singly or doubly charged quantum dot that would act as an efficient radiative recombination center for the opposite carrier type. Heavy doping would guarantee the rapid replenishment of the annihilated majority carriers. Heavy doping effects can arise from both our metallurgical breakthrough of concentrated substitutional donor alloying, and also from the concentration of carriers in lower potential regions due to modulation doping. Both phenomena can contribute substantially to the uses of the invention.

Some significant electrical and magnetic transport properties of these SMSC materials include the transport properties of SMSC/SC heterojunctions, quantum wells, wires and dots. SMSC photonic devices should be interesting as well, because photo-excited carriers have much higher probability of traversing a semiconductor (or SMSC) heterojunction than a true metal/semiconductor junction. For instance, a high spatial resolution Hall effect sensor can be enabled by the thinness of SMSC materials.

Long spin coherence times (exceeding 1 ms) in SMSC systems and across SMSC/Si quantum wells may persist in SMSC materials, particularly when isotopic ²⁸Si is used.

The new technology of SMSC makes it practical to ally modern band structure engineering and carrier confinement concepts. The interplay of band offset effects, modulation doping and heavy metallurgical doping of SMSC materials enables new light emission physics, for instance in quantum mechanically secure telecommunications technologies. That is, enablement of SMSC materials directly anticipates and enables these uses of the materials.

SMSC materials do not have simple properties and could not have been understood by mere extrapolation from prior art knowledge of solid state physics. For instance, conductance and mobility properties are particularly unusual and subtle. The fact that the Fermi level in SMSC materials lies far above the conduction band edge (or far below the valence band edge) invalidates the premises describing all known carrier scattering mechanisms in SMSC materials. Also, impurity scattering is heavily screened, so exhibits a different dependence (on crystal structure, electric field, and temperature) than the light screening encountered traditionally and described in textbooks, beyond just being reduced. This anomalous impurity scattering may actually increase the electron mobility significantly under low field conditions. The mobility under high field conditions is also novel, and generally speaking the high field properties will generally differ significantly from their cases in other materials.

Likewise, the wide separation of conduction band valleys invalidates all the mechanisms known to limit high-speed carrier transport. Our calculations predict a peak velocity of 2×10⁸ cm/s for SMSC InAs, which is an order of magnitude faster than Si or GaAs. We disclose and emphasize that devices can exploit velocity overshoot in practical ways since scattering hot carries into neighboring valleys is difficult due to the large energy difference between valleys, resulting in long ballistic mean free paths. For instance, ballistic transport in transistor bases becomes practical if the base is formed from a SMSC material. Avalanche breakdown is expected to be softer than in materials with small valley separations. Plasmon scattering is expected to play a more important role and may influence avalanche breakdown effects.

Grain boundaries represent an interesting problem for polycrystalline devices formed from SMSC materials, since they accumulate free electrons, in contrast to the depletion and trapping behavior there in conventional semiconductors such as GaAs and Si. Their influence on electronic transport when the system is far from equilibrium has not been investigated. In low electric fields and close to equilibrium, grain boundaries still increase scattering and thus reduce mobility and conductance. Far away from equilibrium their role is not at all clear, and they may paradoxically increase mobility and conductance. Additionally, the complicated interplay of velocity overshoot effects and charge distribution at such boundaries may reduce the conventional effects that grain boundaries have on the current density and may even introduce advantages with respect to impact ionization. For example, since there appears to be an actual accumulation of free carriers at a grain boundary, tunneling barriers between grains should be greatly reduced or eliminated.

SMSC materials technology enable a revolutionary increase in the performance of electrical, power, optoelectronic, spintronic, and single-electron or single-photon devices. Some examples include transistors (e.g. pHEMTs, HBTS, ballistic transistors) that are capable of true THz performance (f_{T} and fₘₐₓ>1 THz), multi-THz-V Johnson figure of merit for power devices (such as 100 V devices at 100 GHz), as well as novel devices such as high performance polycrystalline transistors, spintronic transistors, and single photon emitters and detectors. These capabilities are unprecedented, and have been simply impossible in the past. The disclosure here makes their implementation straightforward.

As semiconductor device dimensions shrink in the pursuit of ever increasing performance, the resistance of both active and passive portions of electronic devices and interconnects becomes the limiting factor. For example, device performance, as described by the unity power gain cutoff frequency, fₘₐₓ, often lags behind the unity current gain cutoff frequency, f_{T}, because of the large series resistance of most devices. By incorporating SMSC materials in these devices, this series resistance can be reduced by more than an order of magnitude, enabling a commensurate increase in fₘₐₓ.

The advantages of heavy doping for producing extremely low contact resistances, as well as a significant reduction in the surface recombination velocity has already been demonstrated for conventional semiconductor⁹. Better SMSC materials technology in the future will enable further improvements in optical and electrical device properties that will have a significant impact on increasing the frequency response and reducing delay times.
⁹ T. J. de Lyon, J. A. Kash, S. Tiwari, J. M. Woodall, D. Yan and F. H. Pollak, “Low surface recombination velocity and contact resistance using p+/p carbon-doped GaAs structures,” Appl. Phys. Lett. v. 56, p. 2442 (1990)

Polycrystalline devices formed from SMSC materials present a unique opportunity. With high enough carrier concentrations and mobilities, polycrystalline devices using SMSC materials can exhibit conductivities approaching that of metallic interconnects, with further advantages of extremely high materials stability due to the robust nature of the covalent bonds in SMSC materials. Furthermore, polycrystalline MOS transistors could be built by simply depositing any suitable insulator on top of a polycrystalline channel formed from SMSC material, possibly achieving performance exceeding that of conventional silicon. Deposition might advantageously be by powder (solid), slurry (liquid suspension), liquid-phase, or vapor phase. For instance, we teach the deposition of a SMSC material on a lattice-mismatched substrate such as a polymer or metal in order to create one or more polycrystalline layers. These are useful for solar cells to convert light into an electric current, large area active and passive electronic devices, and other components or systems. We anticipate such manufacturing methods severally including the deposition of the SMSC material, the state of matter of the SMSC material, a microelectronic optical or electrical device incorporating a SMSC material, a microelectronic component including such a device, a system including such a device, and combinations thereof. We expressly anticipate a device including a SMSC material integrated with conventional silicon CMOS (such as a polycrystalline FET).

SMSC/SC i.e. (semimetal semiconductor-to-semiconductor) heterojunctions themselves constitute a new class of opto & electronic devices. For example, using a SMSC material for the base region of a transistor enables simultaneous reduction in base thickness by order of magnitude (without pinholes) and reduction in base sheet resistance by a further order of magnitude, making base widths of 50-100 Å feasible. While some SMSC materials may exhibit sub-ps minority carrier lifetimes, device performance is not expected to be significantly degraded because the transport time across an ultra-thin SMSC material is expected to be of the order of fs.

Other transistor enhancements are also enabled by SMSC/SC heterojunctions. By optimally combining the low resistance properties of SMSC materials with the high breakdown properties of wide band gap semiconductors, transistor structures can have extremely high frequency-breakdown products. For example, using strain relaxed SMSC InAs as the base region and GaP in the collector will allow transistors to take advantage of the high breakdown field properties of GaP (>1 MV/cm). Similarly, SMSC InAsN combined with GaN collector regions enables even higher breakdown voltages to be achieved.

SMSC materials enable other unique devices such as “metal” base transistors that operate at high temperature. The classical metal base transistor is an NnN transistor (in heterojunction terminology) since it incorporates a very thin n-type metal region sandwiched between an N-type semiconductor emitter and an N-type semiconductor collector. Metal base transistors have only been laboratory curiosities in the past, because the metals employed for the base layer limited carriers to such short mean free paths that transport from emitter to collector was too inefficient. It has been recognized that two major reasons for such poor transistor action were short mean free paths and high quantum mechanical reflection at the base-collector junction interface, due respectively to the materials properties and the discontinuity in the band structure.¹⁰ But using a SMSC material instead of a classical metal in the base allows this discontinuity and the quantum mechanical reflections from it to be greatly reduced, exponentially improving transistor performance.
¹⁰ S. M. Sze and H. K. Gummel, “Appraisal of Semiconductor-Metal-Semiconductor Transistor,” Solid-State Electron., v. 9, p. 751 (1966)

SMSC materials also enable benefits for the gate and channel regions of FET transistors, as well as the base region of bipolar transistors. For example, the particularly good transport properties of SMSC materials enables FETs to achieve frequency response as high as 1 THz (f_{T}=Vₛₐₜ/2 πL=1 THz for V_{ballistic}=2×10⁸ cm/s and L=0.25 μm). Likewise, other transistor technologies such as HBTs would greatly benefit from the incorporation of SMSC materials in the base region, if only to reduce the base sheet resistance significantly.

Additionally, SMSC materials can significantly reduce on-chip phase noise, directly promising better CMOS RF, microwave, and millimeter-wave performance, and with smaller devices. This delays the inevitable but expensive transition to 3D ICs considerably.

Consider for instance the relevance of this SMSC focus to phased-array radar. Using SMSC enabled devices is expected to enable a 10-fold improvement in the coherence of such systems, resulting in tighter phase control and more optimal focusing of beam power. Long baseline SAR transmitters need coherence over a 10 μs window and over the entire extended aperture, but are precluded from this for the foreseeable future at X-band by excessive phase noise. The diffraction limit on two or more apertures separated by a 100 m baseline sets a worst-case timing jitter limit at 33 fs per radian, equivalent to phase-locking a 5 GHz signal to 0.1% accuracy with a 5 THz reference clock. Much jitter is caused by temperature changes in the FET channel with a 1 μs time constant (which can be reduced by apodizing the signal and using HBTs instead of FETs), and from the statistical nature of shot noise (which can be reduced by the extraordinarily high carrier density in a SMSC device). A model of a SMSC-based resonator predicts 5 THz fₘₐₓ, so does not rule out enforcing coherence across hundreds of meters of baseline. Additionally, we anticipate SMSC-based power elements delivering 30 W at 50 W load with an f_{T} of 100 GHz.

Of relevance to infrared detection, we note that 5 THz radiation has 15 μm wavelength in air. This overlaps quantum cascade lasers, which electronic devices have not been effective at doing in the past. We anticipate the use of SMSC materials in devices supporting infrared detection and transmission.

This leads to the issue of devices incorporating SMSC materials. Figure

As described above, quantum confined SMSC materials exhibit unique recombination properties, which enable a new generation of optical emitters, including tunable LEDs and lasers, as well as innovative single photon sources. Furthermore, SMSC materials can make good optical detectors, particularly when combined with conventional semiconductors. We have already demonstrated that InAs/GaP heterojunctions exhibit internal photoemission properties similar to Schottky diodes. Combination of SMSC materials with other semiconductors such as GaAs and InGaAs enables internal photoemission devices where the responsivity is tailored to the application and enable GaAs and Silicon to detect wavelengths with energies less than their band gaps. For instance, we anticipate an APD where the absorption region is a SMSC and the gain region is a wider band gap material. Furthermore, since many SMSC materials support ballistic transport and high electrical fields at heterojunctions, resulting in improved efficiency and enabling new techniques to achieve low noise avalanche amplification of the detected signal.

The flexibility of polycrystalline devices using SMSC materials means that a wide range of variations of these two basic structures are equivalent, including composition of the channel (InAs, InAlAs, InP, InPAs, etc.), composition of the buffer and gate layer (semiconductor, dielectric), and doping (undoped channel, doped channel, modulation doped channel).

Further Discussion of InAs

InAs has unique characteristics. It has been known for many years to exhibit excellent semiconducting properties, including a high saturated drift velocity (8×10⁷ cm/s), a high mobility (20,000 cm²V¹s⁻¹), a narrow band gap (0.35 eV), and a large separation between Γ and L conduction band valleys (0.73 eV).

Despite these excellent semiconductor properties, InAs has yet to find application in high performance or low knee-voltage devices, perhaps (we speculate) due to the lack of suitable quality substrates and suitable heterojunctions.

High quality InAs can be grown¹¹ on GaP despite a high dislocation density¹², yet these InAs films exhibit excellent semiconducting properties¹³. Lattice-mismatched epitaxy between semiconductors with large differences in lattice constant can still give epilayers of high quality, such as the low threading dislocation density of InAs-on-GaP in spite of the 11% lattice mismatch between them. In this unusual system, the lattice strain is accommodated by a plane of defects confined to the hetero-interface (see FIG. 1). These results indicate that when the lattice mismatch is large, 90° (in-plane) dislocations are energetically favored to be formed rather than threading dislocations.
¹¹ J. C. P. Chang, T. P. Chin, and J. M. Woodall, “Incoherent interface of InAs grown directly on GaP(100),” Appl. Phys. Lett., 69 (1996) p. 981.

¹² V. Gopal, P. Chin, A. Vasiliev, J. Woodall, and E. Kvam, “Microstructural and Electrical Characterization of Misfit Diclocations at the InAs/GaP Heterointerface”, Proc. MRS xi+357, 63 (1998).

¹³ V. Gopal, V. K. Souw, E-H. Chen, E. P. Kvam, M. McElfresh, J. M. Woodall, “Temperature-dependent transport properties of InAs films grown on lattice-mismatched GaP”, J. Appl. Phys., 87, no.3; 1 Feb. 2000; p.1350-5.

These unique properties of InAs free surfaces present a unique opportunity for polycrystalline devices formed from SMSC materials. We have already demonstrated polycrystalline InAs with mobilities in excess of 1500 cm²/Vs and carrier concentrations in excess of 1×10¹⁹ cm⁻³. This is in sharp contrast to competing efforts¹⁴, where the production of polycrystalline GaAs resulted in the production of very high resistivity material. By optimizing polycrystalline parameters such as grain size, materials composition, doping, and heterostructure confinement, our theory says we can increase both the free carrier concentration and the mobility by an order of magnitude, enabling polycrystalline devices built using SMSC materials to achieve resistivities less than 100 μΩ-cm, making polycrystalline devices built from SMSC materials suitable for a wide range of applications.
¹⁴ G. M. Metze, H. M. Levy, D. W. Woodard, C. E. C. Wood, and L. F. Eastman, “GaAs integrated circuits by selected area molecular beam epitaxy,” Appl. Phys. Lett., v. 37, p. 628 (1980)

The electrical and optical properties of InAs-on-GaP heterojunctions are also novel and can be useful. Internal photoemission properties of various InGaAs/InAs/GaP structures¹⁵ can be simply described via a metal/Schottky barrier diode model. When light is absorbed by the metal side of a Schottky diode, the photoexcited carriers are “hot,” meaning they have a peak kinetic energy equal to the energy of the absorbed photon. This is in contrast to excited carriers generated by band-to-band excitation in a semiconductor material, where the excited minority carrier usually has only a small amount of kinetic energy, and the remainder of the photon energy is absorbed by a potential energy equal to the band gap energy of the semiconductor. If the kinetic energy of an excited carrier in a metal is greater than the Schottky barrier energy, the photoexcited carrier can cross from the metal into the semiconductor, producing a photocurrent.
¹⁵ E. H. Chen, T. P. Chin, J. M. Woodall, and M. S. Lundstrom, “Electrical Characteristics of Nearly-Relaxed InAs/GaP Heterojunctions,” Appl. Phys. Lett. 70 (1997) 1551.

The internal photoemission results for the InGaAs/InAs/GaP structure are illustrated in FIG. 4. A significant photocurrent is observed for wavelengths down to −1.0 eV, which is significantly smaller than the bandgap of GaP (2.3 eV). Thus, the InAs/GaP heterojunction appears more like a metal-semiconductor junction than a semiconductor-semiconductor junction, with internal photoemission from the InAs strongly contributing to the observed photocurrent.

TABLE II
Properties of InAs films deposited on SiO2. While the
exact structure of these films is not yet known, we believe that
these are polycrystalline films.

| | Room Temperature | | | 77 K | | |
|---|---|---|---|---|---|---|
| | Mobility | Concentration | Resistivity | Mobility | Concentration | Resistivity |
| Sample | (cm²V⁻¹s⁻¹) | cm⁻³ | mΩ-cm | (cm²V⁻¹s⁻¹) | cm⁻³ | mΩ-cm |
| 0.1 μm undoped | 180 | 4.53 × 10¹⁸ | 7.65 | 194 | 3.68 × 10¹⁸ | 8.72 |
| InAs | | | | | | |
| 0.1 μm InAs doped | 41 | 7.37 × 10¹⁹ | 2.09 | 45 | 6.55 × 10¹⁹ | 2.13 |
| to 2 × 10²⁰ cm⁻³ | | | | | | |

Additionally, we have proven the thermal stability of these diodes at temperatures above 700° C., which is far above the temperature at which Au/GaP Schottkys would degrade and fail. To our knowledge, this work is the first demonstration of SMSC/semiconductor diodes exhibiting good thermal stability.

The good thermal stability derives from two features of the materials system. First, these materials exhibit covalent bonds, both within the SMSC material itself, and across interfaces to conventional semiconductors. In contrast, conventional metal-semiconductor interfaces are fragile due to interface reactions and intermixing between the metal and semiconductor. Covalent bonding inhibits chemical reactions and greatly suppresses fast interdiffusion at the SMSC/semiconductor interface. Second, the lattice constant mismatch between InAs and GaP (over 11%) further inhibits interface interdiffusion (i.e. In and As atoms do not fit well into the GaP lattice). Whereas lattice-matched GaAlAs/GaAs has an interface exhibiting strong intermixing, a highly mismatched interface makes intermixing thermochemically unattractive and wants to remain 2D, so improves thermal stability.

Table II illustrates some of the underlying materials science. In particular, note that the InAs films after 2 μm of growth have differential electron mobilities approaching 10,000 cm²V¹s⁻¹ in spite having a threading dislocation density above 10⁹ cm⁻². In parallel, we have reduced threading dislocation density, shown in FIG. 2.

Hyperdoping theory explains how to make other semiconductors semimetallic, such as InGaAs, InP, InAsP, and InGaAsP. We have demonstrated hyperdoping of p-GaAs using an innovative MBE technique, exhibiting the longest minority carrier lifetimes at these doping densities, demonstrating that we can achieve extremely high doping densities without degrading electron transport properties (see FIG. 3). Likewise, we have demonstrated hyperdoping of InP with Si to doping levels of 1×10²⁰ cm⁻³, establishing that hyperdoping is broadly applicable to compound semiconductors, and that hyperdoping can enable the production of SMSC InP. InAsP will exhibit SMSC properties for the same reason, enabling the band gap of SMSC materials to be varied between 0.35 eV and 1.35 eV. Furthermore, because SMSC epitaxial structures can have good quality when built with a large lattice mismatch between the substrate and the SMSC epilayer, we have also demonstrated excellent quality growth of (InAs)_{y}(AlₓGa₁₋ₓAs)₁₋ₓ for y>0.75, enabling heterojunctions including SMSC materials of InAs, InGaAs, and InAlAs.

We have demonstrated InAs/GaP Schottky heterojunction diodes with robust, stable, electrical characteristics in agreement with theory, including ideal breakdown voltages, n-factors, and barrier heights.¹⁶ Indeed, the InAs/GaP heterojunction acts more like a metal/semiconductor (i.e. Schottky) diode than a conventional heterojunction!
¹⁶ E. H. Chen, T. P. Chin, J. M. Woodall, and M. S. Lundstrom, “Electrical Characteristics of Nearly-Relaxed InAs/GaP Heterojunctions,” Appl. Phys. Lett. 70 (1997) 1551.

In short, SMSC InGaAs enables a rich range of heterojunctions between itself and direct, narrow band gap semiconductors such as InAlGaAs, as well as metamorphic heterojunctions with indirect, wide band gap semiconductors such as AlGaP. We have grown SMSC InAs/GaP heterojunctions in accordance with the invention and characterized them to find a novel combination of Schottky diode, and semiconductor heterojunction, characteristics. Furthermore, we have proven SMSC InAs/GaP heterojunctions to be extremely stable against thermal migration, and therefore suitable candidates for consideration in applications where the current densities and thermal dissipation have rendered “normal” heavily doped semiconductors and conventional metal/semiconductor junctions useless.

TABLE III
Sheet carrier concentration and Hall mobility data
for nominally undoped InAs epilayers of various thickness
grown on GaP substrates.

| | 300 K | | 77 K | |
|---|---|---|---|---|
| InAs | Sheet | | Sheet | |
| epilayer | carrier | Hall | carrier | Hall |
| thickness | density | mobility | density | mobility |
| (nm) | (cm⁻²) | (cm²V⁻¹s⁻¹ec) | (cm⁻²) | (cm²V⁻¹s⁻¹ec) |
| 5 | 1.2 × 10¹³ | 40 | 1.2 × 10¹³ | 25 |
| 10 | 1.1 × 10¹³ | 500 | 1.0 × 10¹³ | 360 |
| 15 | 0.75 × 10¹³ | 340 | 0.75 × 10¹³ | 310 |
| 20 | 0.8 × 10¹³ | 460 | 0.8 × 10¹³ | 430 |
| 30 | 1.0 × 10¹³ | 800 | 0.9 × 10¹³ | 730 |
| 250 | 1.0 × 10¹³ | 4000 | 1.0 × 10¹³ | 3780 |
| 500 | 1.2 × 10¹³ | 5310 | 1.1 × 10¹³ | 5390 |
| 1000 | 1.5 × 10¹³ | 7620 | 1.3 × 10¹³ | 8120 |
| 2000 | 2.0 × 10¹³ | 9920 | 1.6 × 10¹³ | 10900 |

Other research focused on developing InAs materials and devices has focused on the excellent semiconducting properties of InAs, but has not recognized the semimetallic properties it can achieve. For example, Averett et al.¹⁷ have demonstrated InAs BJTs and HBTs. Bolognesi et al.¹⁸ have demonstrated InAs HEMTs with a transconductance as high as 800 mS/mm. The 100 Å InAs channel in this device would not be considered a SMSC, because the carrier concentration (1.7×10¹² cm⁻²) and mobility (20,700 cm²V⁻¹s⁻¹) result in calculated resistance value of 177 μW-cm. Boos et al.¹⁹ have demonstrated an InAs HEMT with a transconductance of 800 mS/mm, a measured f_{T} of 180 GHz at V_{DS} of only 0.6 V, and an extrapolated intrinsic f_{T} of 250 GHz, including some multiplication conditions. While none of these results actually use SMSC InAs, they do demonstrate that some of the potential of InAs may be realized.
¹⁷ K. L. Averett, S. Maimon, X. Wu, M. W. Koch and G. W. Wicks, “InAs-based bipolar transistors grown by molecular beam epitaxy,” J. Vac. Sci. Technol. B, v. 20, p. 1213 (2002).

¹⁸ C. R. Bolognesi, M. W. Dvorak, and D. H. Chow, “High-Transconductance Delta-Doped InAs/AlSb HFET's with Ultrathin Silicon-Doped InAs Quantum Well Donor Layer,” IEEE Electron Dev. Lett., v. 19, p. 83 (1998)

¹⁹ J. B. Boos, M. J. Yang, B. R. Bennett, D. Park, W. Kruppa, C. H. Yang and R. Bass, “0.1 μm AlSb/InAs HEMTs with InAs subchannel,” Electronics. Lett., v. 34, p. (1998)

Other research has focused on using InAs to produce spin transistors²⁰. Due to the extremely high mobilities, and the ability to practically eliminate potential barriers between InAs and metals such as Fe, such spin transistors are expected to become an important component of spintronics.
²⁰ D. Grundler, “Ballistic spin-filter transistor,” Phys. Rev. B., v. 63, p. 161307 (2001)

A synthetic semimetal may be produced by using GaSb/InAs superlattices²¹. Due to the unusual type II alignment of the GaSb/InAs heterojunction, the valence band edge of GaSb is higher in energy than the conduction band edge of InAs. This means that this superlattices exhibits GaSb-like holes above the Fermi level and InAs-like electrons below the Fermi level.
²¹ R. Magri and A. Zunger, “Effects of interfacial atomic segregation and intermixing on the electronic properties of InAs/GaSb superlattices,” Phys. Rev. B., v. 65, p. 165302 (2002)

Furthermore, the valence band of GaSb may donate electrons to the InAs conduction band, and the InAs conduction band may donate holes to the GaSb valence band. While such GaSb/InAs superlattices are expected to exhibit interesting semimetallic properties, they are difficult to produce experimentally and have not yet found significant device application.

It is our intent that these examples be generalized to the complementary case wherein throughout the description, the valence band and conduction band are swapped, n-type and p-type are swapped, accumulation and depletion are swapped, and electrons and holes are swapped.

We anticipate claiming materials and/or devices using the saturation drift velocity, peak velocity in velocity overshoot conditions, ballistic scattering lengths, peak velocity, recombination parameters including radiative, SRH recombination, and Auger recombination in heterojunction and quantum confined SMSC materials dependent on SMSC materials.

We anticipate claiming such optimizations in devices such as FETs, HBTs, metal base transistors, and LEDs.

We anticipate claiming the dependence of methods for doping (including hyperdoping, modulation doping, and surface doping) on the transport properties of SMSC materials.

We anticipate claiming the relation of charge distribution and strain to the band structure, recombination, transport, and optical & electrical transport properties of these materials and devices.

We anticipate claiming the quantum confined structures that achieve SMSC materials within 0D, 1D, and 2D quantum confined heterostructures, and spintronics effects, especially those that use the uniquely high conductivity and ballistic transport of SMSC materials.

As those ordinarily skilled in the art will appreciate, a significant effort has been made to provide much more than just process recipes in this disclosure. Instead, with the hope of facilitating a complete appreciation of the full scope the invention and the numerous applications of the hyperdoping, the inventors have attempted to explain the underlying physics in detail. The reader should understand, however, that hyperdoping is a new technique, and there exists a possibility that certain of the inventors' theories of operation may not be 100% correct. It is important to note that errors or gaps in the understanding of how or why an invention works do not undermine the validity of a patent. See Newman v. Quigg, 720 F.2d 1565, 1570 (Fed. Cir. 1983) (“[I]ₜ is axiomatic that an inventor need not comprehend the scientific principles on which the practical effectiveness of his invention rests.”).

Furthermore, notice is hereby given that the applicants intend to seek, and ultimately receive, claims to all aspects, features and applications of the current invention, both through the present application and through continuing applications, as permitted by 35 U.S.C. §120, etc. Accordingly, no inference should be drawn that applicants have surrendered, or intend to surrender, any potentially patentable subject matter disclosed in this application, but not presently claimed. In this regard, potential infringers should specifically understand that applicants may have one or more additional applications pending, that such additional applications may contain similar, different, narrower or broader claims, and that one or more of such additional applications may be designated as not for publication prior to grant.

1. A method of making a compound semiconductor material act as a semimetal semiconductor, comprising the step of doping said material to a dopant density exceeding 1×10¹⁹ cm⁻³ while maintaining majority carrier mobility sufficient to keep the conductivity above 10,000 mhos.

2. The method of claim 1 wherein the undoped form of said compound material exhibits an electronic affinity larger than 4.1 eV.

3. The method of claim 1 wherein hyperdoping is utilized.

4. The method of claim 1 wherein the doping is not spatially separated from the SMSC material.

5. The method of claim 1 wherein said compound semiconductor material comprises an alloy of phosphorous.

6. The method of claim 1 wherein said step of doping employs a growth temperature between 500 and 800 kelvins.

7. The method of claim 6 wherein said step of doping utilizes molecular beam epitaxy.

8. The method of step 1 where the free carrier concentration exceeds 1×10¹⁹ cm⁻³.

9. The method of step 1 where the free carrier concentration exceeds 2×10¹⁹ cm⁻³.

10. The method of step 1 where the free carrier concentration exceeds 4×10¹⁹ cm⁻³.

11. The method of step 1 where the free carrier concentration exceeds 8×10¹⁹ cm⁻³.

12. The method of step 1 where said material is a bulk material.

13. The method of step 12 where said bulk material is at least 30 nm thick.

14. The method of step 12 where said bulk material is at least 50 nm thick.

15. The method of step 12 where said bulk material is at least 100 nm thick.

16. A compound semiconductor material with conductivity above 10,000 mhos, and free carrier concentration above 10¹⁹ cm⁻³.

17. The material of claim 16 where said compound semiconductor material is a III-V compound semiconductor and contains indium.

18. A microelectronic device including from a semimetal semiconductor.

19. A microelectronic device in accordance with claim 18, wherein said device includes a rectifying contact between said semimetal semiconductor and a semiconductor.

20. A microelectronic device in accordance with claim 18, wherein said device includes a high-conductivity channel formed from said semimetal semiconductor.
